(19) United States
(12) Patent Application Publication
(10) Pub. No.: US 2010/0188809 A1
(43) Pub. Date: Jul. 29, 2010

(54) Radiator For Computer Memory

(76) Inventors: Yung-Lin HSU, Taipei Hsien (TW); Chia-Ming Tung, Taipei Hsien (TW)

Correspondence Address: FRENKEL & ASSOCIATES, 3975 UNIVERSITY DR., STE. 330, FAIRFAX, VA, 22030, US

(21) Appl. No.: 12/359,711

(22) Filed: Jan. 26, 2009

(51) Int. Cl. H05K 7/20

(52) U.S. Cl. 361/679.47; 361/679.54

(57) ABSTRACT

A radiator has a main heat sink and at least one secondary heat sink. The main heat sink has a heat conductor and multiple longitudinal fins. The heat conductor is formed from two mounting panels being connected along connecting beams being wider than the panel so forming a mounting space and having multiple conducting posts being formed on and protruding from the connecting beams and at least one trough formed in one mounting panel. The longitudinal fins are mounted on the conducting posts to dissipate heat. The secondary heat sink has a conducting bar mounted in and protruding from the trough with multiple transverse fins mounted on the connecting bar. A computer memory is mounted in the mounting space for improved efficacy.

### BACKGROUND OF THE INVENTION

1. Field of the Invention

The present invention relates to a radiator, especially to a radiator for computer memory improved efficacy.

2. Description of the Prior Arts

When in use, electric devices produce heat that must be dissipated. Therefore, electric devices are designed to maintain themselves at normal working temperature. However, as computer components are reduced in size, heat produced per unit area is increased so heat builds up. Therefore, computer components are mounted on a conventional heat sink to aid heat dissipation.

When, a memory computer component exceeds a certain temperature, a speed and efficiency of the memory is decreased. Above a critical temperature, the memory may be ruined and must be replaced.

To overcome the shortcomings, the present invention provides a radiator for the computer to mitigate or obviate the aforementioned problems.

### SUMMARY OF THE INVENTION

The main objective of the present invention is to provide a radiator for computer memory with improved efficacy.

A radiator has a main heat sink and at least one secondary heat sink. The main heat sink has a heat conductor and multiple longitudinal fins. The heat conductor is formed from two mounting panels being connected along connecting beams being wider than the panel so forming a mounting space and having multiple conducting posts being formed on and protruding from the connecting beams and at least one trough formed in one mounting panel. The longitudinal fins are mounted on the conducting posts to dissipate heat. The secondary heat sink has a conducting bar mounted in and protruding from the trough with multiple transverse fins mounted on the connecting bar. A computer memory is mounted in the mounting space for improved efficacy.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a radiator in accordance with the present invention;

FIG. 2 is an exploded perspective view of the radiator in FIG. 1;

FIG. 3 is an enlarged partially exploded perspective view of the radiator in FIG. 1;

FIG. 4 is a cross sectional side view of the radiator in FIG. 1; and

FIG. 5 is a perspective view of the radiator in FIG. 1 further comprising a blower.

### DETAILED DESCRIPTION OF THE PREFERRED EMBODIMENTS

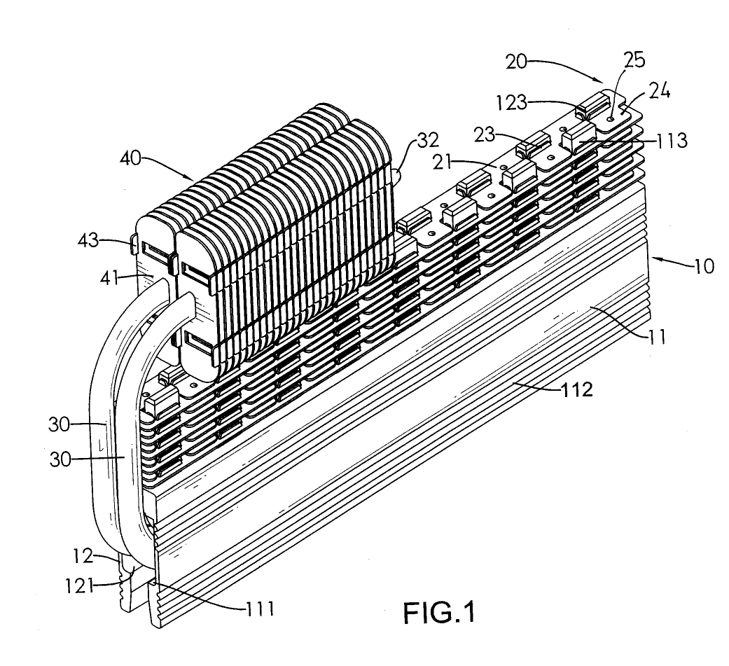

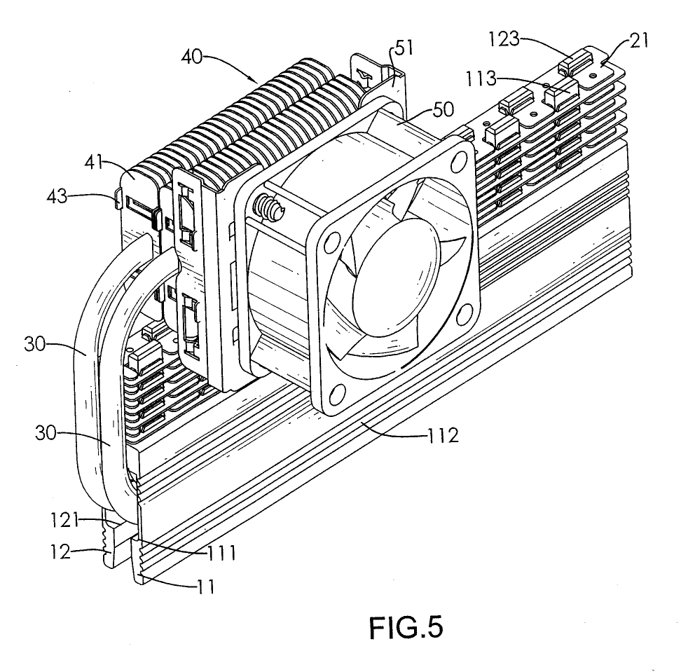

With reference to FIGS. 1, 2 and 5, a radiator for a computer memory in accordance with the present invention comprises a main heat sink and may further comprise at least one secondary heat sink (40) and a blower (50).

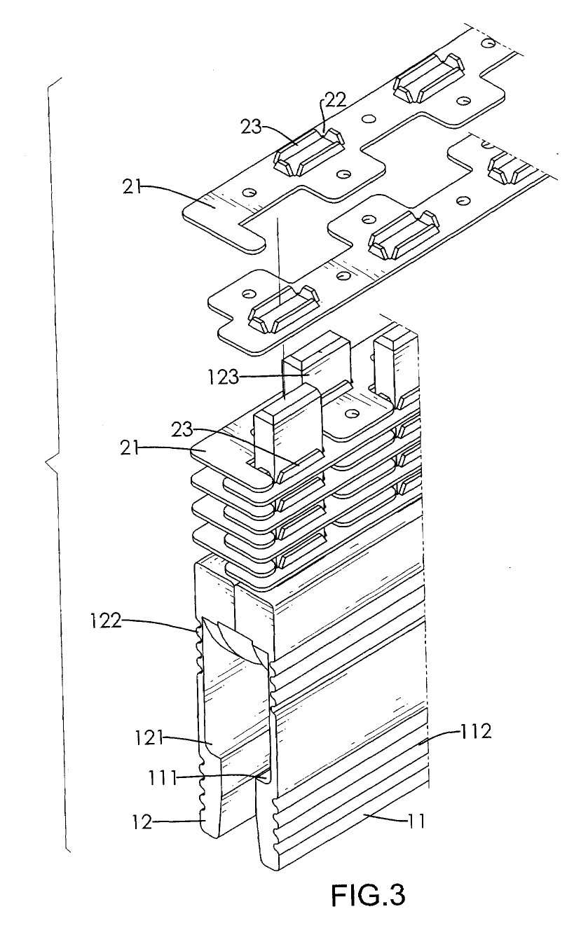

With further reference to FIG. 3, the main heat sink comprises a heat conductor (10) and multiple longitudinal fins (20).

The heat conductor (10) has two mounting panels (11, 12). The mounting panels (11, 12) are attached to each other, may be formed together or may be connected using fasteners, welding or the like and each mounting panel (11, 12) has a connecting beam, an outer surface, an inner surface, a trough (111, 121), multiple dissipating ribs (112, 122) and multiple conducting posts (113, 123).

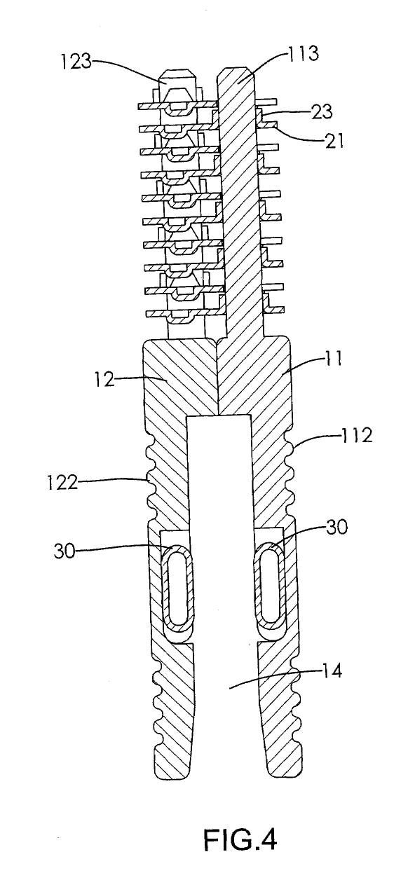

The connecting beam of the mounting panel (11, 12) is formed on and protrudes from the mounting panel (11, 12), is wider than the mounting panel (11, 12) and is attached to and may be formed with the connecting beam of the other mounting panel (11, 12) to form a mounting space (14) as shown in FIG. 4.

The trough (111, 121) is formed in the inner surface of the mounting panel (11, 12) adjacent to the connecting beam.

The dissipating ribs (112, 122) are formed, may be longitudinally, on the outer surface of the mounting panel (11, 12).

The conducting posts (113, 123) are separately formed on and protrude transversely from the connecting beam of the mounting panel (11, 12) and may be quadrangular. The conducting posts (113) of one mounting panel (11) may be arranged alternately with the conducting posts (123) of the other mounting panel (12).

The longitudinal fins (20) are parallelly stacked on the conducting posts (113, 123) of one mounting panel (11) and each longitudinal fin (20) has a mounting edge, a sinuous edge, multiple mounting holes (22), multiple spacers (23), multiple protrusions (24) and multiple optional bosses (25).

The mounting holes (22) are formed through the mounting edge of the longitudinal fins (20), are mounted respectively around the conducting posts (113, 123) of one mounting panel (11, 12) and may be quadrangular.

The spacers (23) are formed respectively adjacent to the mounting holes (22), protrude from the longitudinal fins (20) and abut an adjacent longitudinal fin (20) to form an interval between the longitudinal fins (20). In alternative embodiment, each spacer (23) may be implemented as four sub spacers. The sub spacers are arranged around an edge of each mounting hole (22).

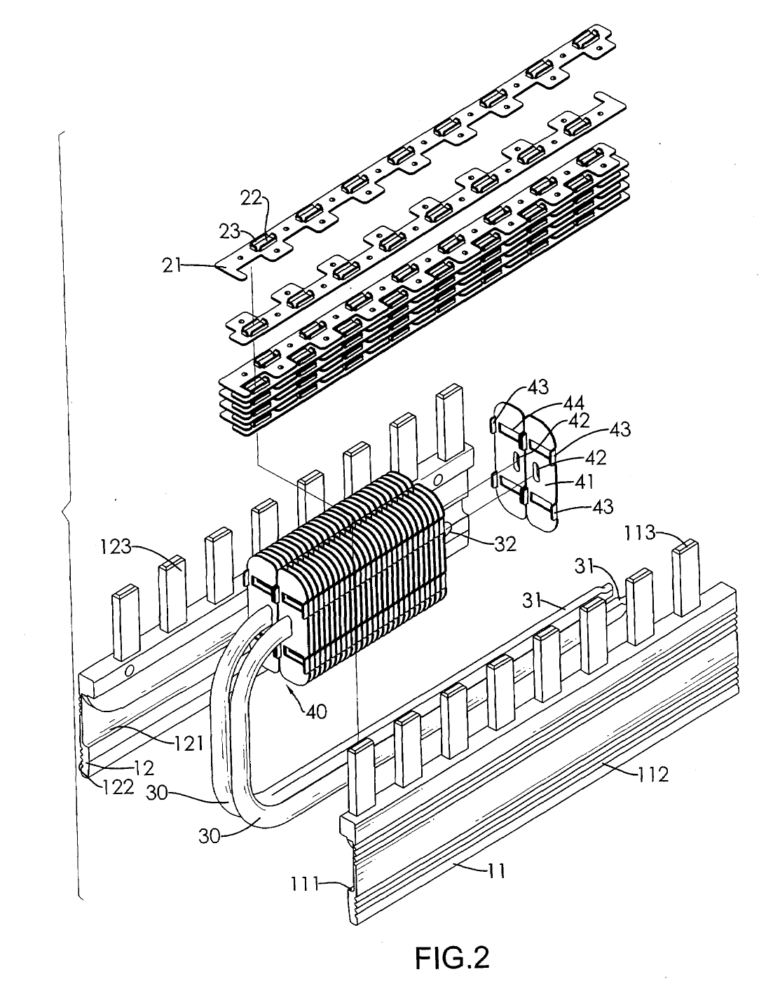

The protrusions (24) are formed on and protrude from the sinuous edge, are mounted respectively in intervals between adjacent conducting posts (111, 121) of the other mounting panel (11, 12) and abut an adjacent fin (20). Each protrusion (24) may have two transverse edges respectively abutting adjacent spacers (23) of the adjacent fin (20) as shown in FIGS. 2 and 4.

The bosses (25) are formed on and protrude from the longitudinal fin (21) and each boss (25) may be disposed between two adjacent mounting holes (22) or on each protrusion (24) to improve airflow over the longitudinal fins (20).

The at least one secondary heat sink (40) is mounted on the main heat sink and each secondary heat sink (40) comprises a conducting bar (30) and multiple transverse fins (41).

The conducting bar (30) may be a heat pipe, is mounted in the trough (111, 121) of one of the mounting panels (11, 12) and has a proximal end (31) and a distal end (32). The proximal end (31) is mounted in the trough (111, 121) of the mounting panel (11, 12). The distal end (32) of the conducting bar (30) extends out from the trough (111, 121) of the mounting panel (11, 12).

The transverse fins (41) are parallelly stacked on the distal end (32) of conducting bar (30) and each transverse fin (41) has two side edges, a bar hole (42), multiple supporting protrusions (43) and at least one optional vent (44). The bar hole (42) is formed through the transverse fin (41), corresponds to and is mounted on the distal end (32) of the conducting bar (30). The supporting protrusions (43) are formed on the side edges and abut an adjacent transverse fin (41) to form an interval. The at least one vent (44) is formed through the transverse fin (41), aligns with vents (44) in adjacent transverse fins (41) and allows air to pass through the at least one secondary heat sink (40).

The blower (50) is mounted on the at least one secondary heat sink (40) and pushes air through the at least one secondary heat sink (40).

When a computer memory is mounted in the mounting space (14) of the heat conductor (10), the computer memory can contact the mounting panels (11) and the secondary heat sink (40) to allow heat generated by the computer memory to be conducted away by the mounting panels (11) and secondary heat sink (40). Then, the heat is lost to surrounding air by the fins (20, 41). Therefore, the radiator maintains the computer memory within normal working temperature for improved efficacy.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A radiator for a computer memory comprising
a main heat sink comprising
a heat conductor having
two mounting panels being attached to each other and each mounting panel having
a connecting beam being formed on and protruding from the mounting panel, being wider than the mounting panel and being attached to the connecting beam of the other mounting panel to form a mounting space;
an outer surface;
an inner surface; and
multiple first conducting posts being separately formed on and protruding from the connecting beam of the mounting panel; and
multiple longitudinal fins being parallelly stacked on the conducting posts of the mounting panel.

2. The radiator as claimed in claim 1, wherein each longitudinal fin further has
a mounting edge;
a sinuous edge;
multiple mounting holes being formed through the mounting edge and mounted respectively around the conducting posts of one mounting panel and having a edges; and
multiple protrusions being formed on and protruding from the sinuous edge, mounted respectively in intervals between adjacent conducting posts of the other mounting panel and abutting an adjacent fin.

3. The radiator as claimed in claim 2, wherein
at least one mounting panel further has a trough being formed in the inner surface of the mounting panel adjacent to the connecting beam; and
the radiator further has at least one secondary heat sink being mounted on the main heat sink and having
a conducting bar being mounted in the trough of one of the mounting panels and having
a proximal end being mounted in the trough; and
a distal end extending from the trough; and
multiple transverse fins being parallelly stacked on the distal end of the conducting bar and each transverse fin has
two side edges;
a bar hole being formed through the transverse fin, corresponding to and being mounted on the distal end of the conducting bar; and
multiple supporting protrusions being formed on the side edges and abutting an adjacent transverse fin to from an interval.

4. The radiator as claimed in claim 3, wherein each longitudinal fin further has multiple spacers being formed adjacent respectively to the mounting holes, protruding from the longitudinal fins and abutting the adjacent longitudinal fin to form an interval between longitudinal fin.

5. The radiator as claimed in claim 4, wherein each longitudinal fin further has multiple bosses being formed on and protruding from the longitudinal fin.

6. The radiator as claimed in claim 1, wherein each mounting panel further has multiple dissipating ribs being formed on the outer surface of the mounting panel.

7. The radiator as claimed in claim 2, wherein each mounting panel further has multiple dissipating ribs being formed on the outer surface of the mounting panel.

8. The radiator as claimed in claim 3, wherein each mounting panel further has multiple dissipating ribs being formed on the outer surface of the mounting panel.

9. The radiator as claimed in claim 4, wherein each mounting panel further has multiple first dissipating ribs being formed on the outer surface of the first mounting panel.

10. The radiator as claimed in claim 5, wherein each mounting panel further has multiple first dissipating ribs being formed on the outer surface of the first mounting panel.

11. The radiator as claimed in claim 3, wherein the radiator further has a blower being mounted on the at least one secondary heat sink.

12. The radiator as claimed in claim 4, wherein the radiator further has a blower being mounted on the at least one secondary heat sink.

13. The radiator as claimed in claim 5, wherein the radiator further has a blower being mounted on the at least one secondary heat sink.

14. The radiator as claimed in claim 6, wherein the radiator further has a blower being mounted on the at least one secondary heat sink.

15. The radiator as claimed in claim 7, wherein the radiator further has a blower being mounted on the at least one secondary heat sink.

16. The radiator as claimed in claim 8, wherein the radiator further has a blower being mounted on the at least one secondary heat sink.

17. The radiator as claimed in claim 9, wherein the radiator further has a blower being mounted on the at least one secondary heat sink.

18. The radiator as claimed in claim 10, wherein the radiator further has a blower being mounted on the at least one secondary heat sink.
